(19) United States
(12) Patent Application Publication
(10) Pub. No.: US 2025/0316442 A1
(43) Pub. Date: Oct. 9, 2025

(54) Microscope System

(71) Applicant: Hitachi, Ltd., Chiyoda-ku (JP)

(72) Inventors: Fumiaki ICHIHASHI, Tojyo (JP); Toshiaki TANIGAKI, Tojyo (JP)

(21) Appl. No.: 18/865,755

(22) PCT Filed: May 20, 2022
(86) PCT No.: PCT/JP2022/020935

§ 371 Date: Nov. 14, 2024

(51) Int. Cl. H01J 37/22; G03H 5/00; H01J 37/147; H01J 37/28

(52) U.S. Cl. CPC H01J 37/222; G03H 5/00; H01J 37/1472; H01J 37/28; H01J 2237/2614

(57) ABSTRACT

An object of the present invention is to provide a microscope system capable of separating electron waves acquired by a microscope and having passed through multiple layers including a sample into electron wave information originating from each layer, thereby improving the image quality of the sample to be observed. The microscope system of the present invention includes: a microscope which deflects an electron beam incident on a first layer, a second layer, and a third layer to acquire multiple pieces of electron wave information; and a control device which changes a focal position of the multiple pieces of electron wave information acquired by the microscope to the third layer, and calculates the amplitudes and phases of electron waves originating from the first layer, the second layer, and the third layer, respectively based on the amplitudes and phases included in the electron wave information after the focal position is changed.

### TECHNICAL FIELD

This invention relates to a microscope system.

### BACKGROUND ART

Elucidating the reaction mechanism of catalysts is essential for highly efficient hydrogen production, artificial photosynthesis, and fuel cells, which aims to achieve carbon neutrality. There has recently been an increasing demand for in-situ observation by an electron microscope of morphological and physical property changes of catalysts during actual operation, that is, in gas or liquid environments. When the in-situ observation is performed, a membrane type environmental control holder has been attracting attention because it is a method effective in introducing atmospheric gas or liquid into the holder. There has been disclosed in Patent Literature 1, for example, a method of observing a sample by sealing liquid or gas in a membrane type holder having a sealing region.

### CITATION LIST

### Patent Literature

Patent Literature 1: U.S. Unexamined Patent Application Publication No. 2015/348745

### SUMMARY OF INVENTION

### Technical Problem

However, in the membrane type holder, there is a possibility that since an electron beam penetrates not only a sample but also membranes above and below the sample, a signal originating from the membranes is superimposed on a signal originating from the sample, thereby reducing the image quality of the sample. In particular, reaction fields (electromagnetic fields) affecting the characteristics of chemical reactions in catalysts, electrodes, and the like are extremely small signals, and their analysis requires ultra-high accurate measurements, so that any degradation in the image quality of the sample can be fatal.

An object of the present invention is to provide a microscope system capable of separating electron waves acquired by a microscope and having passed through multiple layers including a sample into electron wave information originating from each layer, thereby improving the image quality of the sample to be observed.

### Solution to Problem

In order to solve the above problems, a microscope system of the present invention includes: a microscope which deflects an electron beam incident on a first layer, a second layer, and a third layer to acquire multiple pieces of electron wave information; and a control device which changes a focal position of the multiple pieces of electron wave information acquired by the microscope to the third layer, and calculates the amplitudes and phases of electron waves originating from the first layer, the second layer, and the third layer, respectively based on the amplitudes and phases included in the electron wave information after the focal position is changed.

### Advantageous Effects of Invention

According to the present invention, it is possible to provide a microscope system capable of separating electron waves acquired by a microscope and having passed through multiple layers including a sample into electron wave information originating from each layer, thereby improving the image quality of the sample to be observed.

### BRIEF DESCRIPTION OF DRAWINGS

FIG. 1 is a schematic diagram of a microscope system.

FIG. 2 is an example of a screen output to a display device when an incident angle and incident direction of an electron beam are set.

FIG. 3 is a flowchart showing processing in a transmission type electron microscope during its measurement.

FIG. 4 is a cross-sectional schematic diagram showing the manner in which an electron beam passes through a membrane type holder.

FIG. 5 is a cross-sectional schematic diagram showing the manner in which the electron beam passes through the membrane type holder when the electron beam is tilted.

FIG. 6 is a flowchart showing processing in a control device during analysis.

### DESCRIPTION OF EMBODIMENTS

An embodiment of the present invention will be described below with reference to the drawings. It should be noted that in the following description, the same components are indicated by the same reference numerals, and the repeated description thereof may be omitted.

### First Embodiment

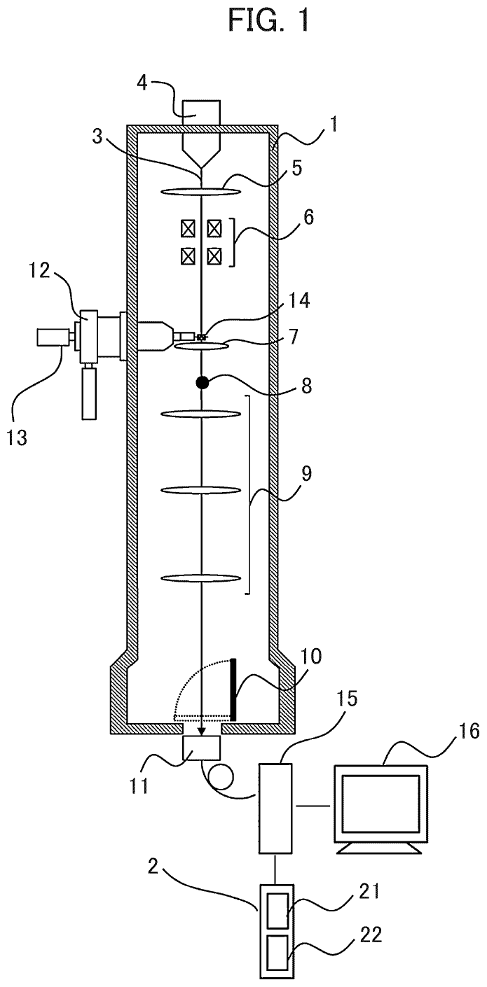

A microscope system according to a first embodiment will be described. FIG. 1 is a schematic diagram of the microscope system. As shown in FIG. 1, the microscope system is constituted of a transmission type electron microscope 1 and a control device 2 (analysis PC).

A description will first be made about the configuration of the transmission type electron microscope 1. The transmission type electron microscope 1 includes an electron source 4, a converging lens 5, a deflector 6, an objective lens 7, an electron beam biprism 8, an imaging lens system 9, a fluorescent plate 10, a camera 11, a goniometer 12, a control PC 15, and a display device 16.

The electron source 4 includes a cathode which emits an electron beam 3, and an accelerating tube which accelerates the electron beam 3. The converging lens 5 converges the electron beam 3 emitted and accelerated by the electron source 4. The deflector 6 deflects the incident angle of the electron beam 3 converged by the converging lens 5. The objective lens 7 is a lens which adjusts the size of the electron beam 3 irradiated onto a sample 40, and has an upper electrode piece arranged on the upstream side of the electron beam 3, and a lower electrode piece arranged on the downstream side of the electron beam 3. The electron beam biprism 8 superimposes an electron wave which has passes through the sample 40 to be observed and a reference electron wave which serves as a phase reference, thereby forming an electron beam interference fringe (hologram). The imaging lens system 9 is comprised of a plurality of lenses for enlarging and imaging the hologram. The fluorescent plate 10 is a plate which emits fluorescence by the electron beam 3 imaged by the imaging lens system 9. The camera 11 (imaging unit) acquires a hologram image obtained by the imaging lens system 9 when the fluorescent plate 10 is open.

The goniometer 12 is for adjusting the position of the sample holder 13 to be attached. Further, when the sample holder 13 is attached to the goniometer 12, a membrane type holder 14 which is provided at the tip of the sample holder 13 is positioned between the upper electrode piece and the lower electrode piece of the objective lens 7. Here, the membrane type holder 14 supports the sample 40 to be observed, and is separated from the sample 40 by a first membrane 41 above the sample 40 and a second membrane 42 below the sample 40 so that atmospheric pressure gas or liquid can be introduced. Therefore, the sample holder 13 and the goniometer 12 can be regarded as a holding unit which holds the first membrane 41, the sample 40, and the second membrane 42. Incidentally, in the following description, the first membrane 41 may be referred to as a first layer, the sample 40 as a second layer, and the second membrane 42 as a third layer.

The control PC 15 controls the electron source 4, the converging lens 5, the deflector 6, the objective lens 7, the electron beam biprism 8, the imaging lens system 9, the camera 11, and the goniometer 12, and stores the hologram image acquired by the camera 11 in a memory unit not shown. The display device 16 outputs the control contents of the control PC 15, the hologram image acquired by the camera 11, and the like, and is, for example, a display.

In the transmission type electron microscope 1 having the above-described configuration, the electron beam 3 emitted from the electron source 4 passes through the converging lens 5 and an upper magnetic pole piece of the objective lens 7, and is irradiated onto the membrane type holder 14. The electron beam 3 having passed through the membrane type holder 14 passes through a lower magnetic pole piece of the objective lens 7 and the imaging lens system 9 comprised of the multiple lenses. When the fluorescent plate 10 is open, information of the electron wave acquired by the camera 11 is output to the display device 16. Further, in the above-mentioned transmission type electron microscope 1, since the electron beam biprism 8 is provided between the membrane type holder 14 and the imaging lens system 9, it is possible to perform electron beam holography observation that is capable of obtaining phase information of the electron wave. Incidentally, the number of electron beam biprisms 8 is not particularly limited, and may be two. Further, as long as the phase information of the electron wave can be obtained, methods other than the electron beam holography, and other charged particle devices such as a scanning transmission electron microscope, a scanning electron microscope, etc. may be used.

Next, the configuration of the control device 2 (analysis PC) will be described. The control device 2 changes a focal position of multiple electron wave information (e.g., hologram images) stored in the memory unit of the control PC 15 to the second membrane 42, and calculates the amplitude and phase of electron waves originating from the first membrane 41, the sample 40, and the second membrane 42, based on the amplitude and phase included in the electron wave information after changing of the focal position. The exchange of data between the control PC 15 of the transmission type electron microscope 1 and the control device 2 may be performed via a dedicated communication line or network, or via a recording medium. Further, the control device 2 is a PC for analyzing the data acquired by the transmission type electron microscope 1, and has a focal point changing unit 21 and an assumed data calculating unit 22 each stored in a memory as programs corresponding to each function executed by a processor.

The focal point changing unit 21 changes the focal position with respect to the amplitude and phase of the electron wave. The assumed data calculating unit 22 individually assumes the amplitude and phase of the electron wave originating from each layer, and corrects data obtained by superimposing the individual assumed data of amplitude and phase while comparing the same with experimental data actually acquired by the camera 11.

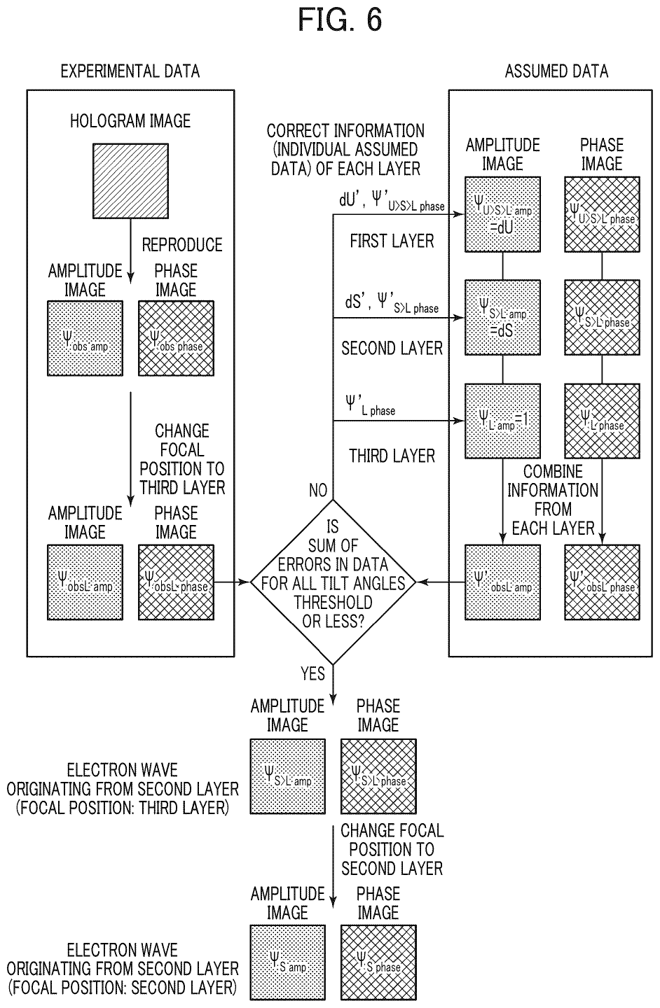

Incidentally, a specific analysis method conducted by the focal point changing unit 21 and the assumed data calculating unit 22 will be described later with reference to FIG. 6.

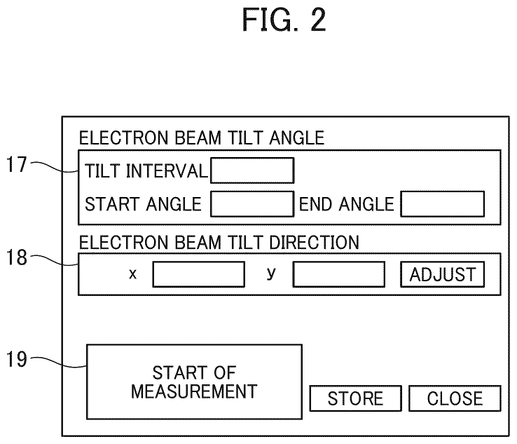

FIG. 2 is an example of a screen output to the display device when setting the incident angle and incident direction of the electron beam. A user inputs a tilt interval, a tilt start angle, and a tilt end angle of the electron beam 3 when observing the sample 40 to an electron beam tilt angle setting unit 17, and inputs a tilt direction of the electron beam 3 when observing the sample 40 to an electron beam tilt direction setting unit 18. When the user operates a start button 19 after the input to each setting unit is completed, the control PC 15 of the transmission type electron microscope 1 starts measuring.

Here, when the electron beam 3 is tilted, astigmatism, changes in the electron beam 3 relative to the electron beam biprism 8, other changes in an electron beam path, and the like occur. Therefore, the transmission type electron microscope 1 is also provided with a function for correcting these. As a correction method, there is considered a method of registering an optical adjustment value for each tilt condition of the electron beam 3 in advance, and if the tilt condition matches the registered tilt condition during measurement, reading the optimal adjustment value to thereby control the transmission type electron microscope 1. In this correction method, when the tilt condition does not match the registered tilt condition, an optimal adjustment value is calculated by an approximation function or machine learning, on the basis of each registered tilt condition and its optimal adjustment value to thereby control the transmission type electron microscope 1. Note that the correction method is not limited to this method.

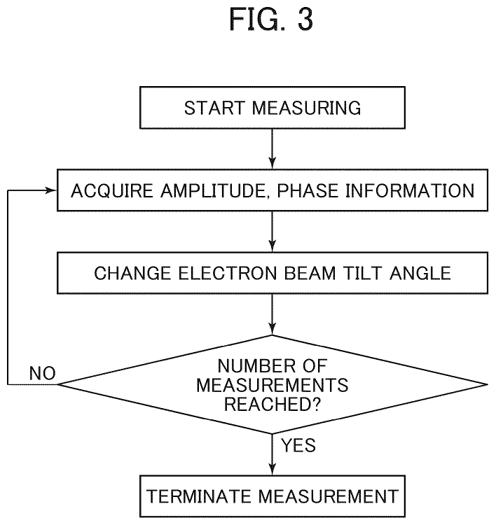

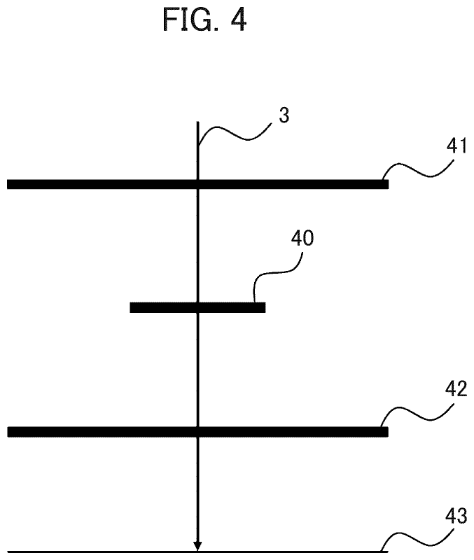

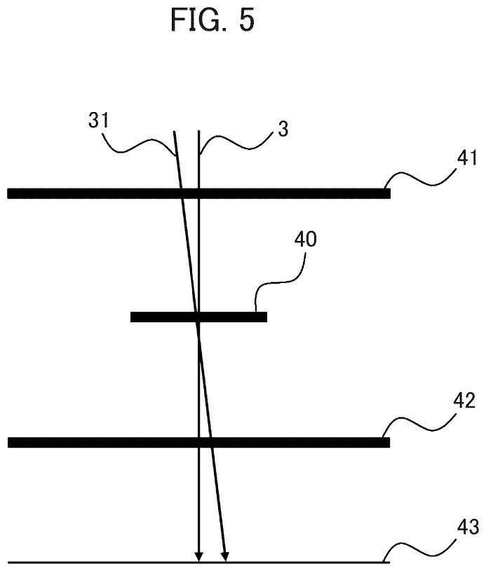

FIG. 3 is a flowchart showing processing in the transmission type electron microscope during its measurement. FIG. 4 is a schematic cross-sectional view showing the manner in which an electron beam passes through a membrane type holder. FIG. 5 is a schematic cross-sectional view showing the manner in which the electron beam passes through the membrane type holder when the electron beam is tilted.

After setting of the incident angle and incident direction of the electron beam 3 is completed, the measurement is started. The control PC 15 then controls the deflector 6 to deflect the electron beam 3 to a predetermined incident angle and incident direction, and causes the electron beam 3 to pass through the first layer, second layer, and third layer in this order after its deflection to thereby acquire a hologram image by the camera 11 at the focal position 43 during the measurement. Note that the focal position 43 during the measurement is set within 100 μm from the position of the sample 40 to be observed.

Thereafter, the control PC 15 controls the deflector 6 to change the incident angle and incident direction of the electron beam 3 (refer to the inclined electron beam 31 in FIG. 5), and again transmits the electron beam 3 through the first layer, the second layer, and the third layer in that order, thereby obtaining a hologram image at the focal position 43 during the measurement by the camera 11. The control PC 15 repeats such measurements, and when a predetermined number of measurements are reached, terminates the measurement, and stores a plurality of hologram images different in the incident angle in the storage unit thereof.

Next, the basic principle of an analysis method for separating the multiple-transmitted electron waves acquired by the microscope and including the sample 40 into electron wave information originating from each layer will be described. In the present embodiment, the amplitude and phase of the electron wave information originating from each layer are separated from the electron wave information in a state of being focused on the third layer (second membrane 42) by an analysis algorithm of electron beam tomography. Note that the electron wave is subjected to the action of a gradual phase change which spreads from the three layers, i.e., the first membrane 41, the sample 40, and the second membrane 42 to the surroundings. Further, in order to simplify the model, the first membrane 41, the sample 40, and the second membrane 42 are assumed to be thin phase objects with no thickness (which only impart a phase change to the electron wave passing through them).

First, the amplitude will be described. If the amplitude information in the second membrane 42 is Ψ_{L amp}, then since there is no information propagation in the second membrane 42, Ψ_{L amp}=1. Further, amplitude information of the electron wave observed in the second membrane 42 can be represented as Ψ_{obsL amp}=Ψ_{U>S>L amp}×Ψ_{S>L amp}. Here, Ψ_{U>S>L amp} is amplitude information regarding the electron wave which has transmitted through the first membrane 41 and the sample 40 and propagated to the second membrane 42. Ψ_{S>L amp} is amplitude information regarding the electron wave which has transmitted through the sample 40 and propagated to the second membrane 42. Further, since Ψ_{U>S>L amp} can be approximated to exp(−dU) using an amplitude change coefficient dU when the electron beam 3 passes through the first membrane 41. Ψ_{S>L amp} can be approximated to exp(−dS) using the amplitude change coefficient dS when the electron beam 3 passes through the sample 40. Therefore, the amplitude information of the electron wave in the second membrane 42 can be represented as Ψ_{obsL amp}=exp{−(dU+dS)}.

Next, the phase will be described. The phase information of the electron wave observed in the second membrane 42 can be expressed as Ψ_{obsL phase}=Ψ_{U>S>L phase}+Ψ_{S>L phase}+Ψ_{L phase}. Here, Ψ_{U>S>L phase} is phase information regarding the electron wave which has passed through the first membrane 41 and the sample 40 and propagated to the second membrane 42, Ψ_{S>L phase} is phase information regarding the electron wave which has passed through the sample 40 and propagated to the second membrane 42, and Ψ_{L phase} is phase information in the second membrane 42.

Thus, the amplitude and phase of the electron wave observed in the second membrane 42 can be expressed as the sum of the amplitude change coefficient and the phase information in the projection direction originating from each layer. Therefore, in the present embodiment, a plurality of projection images are obtained by changing the angle of incidence of the electron beam 3, and the amplitude change coefficient and phase information derived from each layer are calculated by utilizing an algorithm of electron beam tomography which reconstructs a three-dimensional structure.

An algorithm for separating the amplitude and phase of the electron wave originating from each layer (the sample 40 as the second layer in particular) will be specifically described with reference to FIG. 6. FIG. 6 is a flowchart showing processing in the control device during its analysis.

First, the control device 2 acquires a hologram image for each incident angle stored in the storage unit of the control PC 15 in the transmission type electron microscope 1 and reproduces the amplitude information and the phase information. Further, the focal position changing unit of the control device 2 changes the focal position to the second membrane 42 for the reproduced amplitude information Ψ_{obs amp} and phase information Ψ_{obs}, and obtains amplitude information Ψ_{obsL amp} and phase information Ψ_{obsL phase}. That is, regarding the image focused on the second membrane 42, experimental data of the amplitude change coefficient (dU+dS) =−logΨ_{obsL amp} and phase information Ψ_{obsL phase} are obtained for each incident angle.

Next, the assumed data calculating unit 22 of the control device 2 individually assumes the amplitude change coefficient and phase information of the electron wave originating from each layer. The individual assumed data of the amplitude change coefficient and phase information of the electron wave originating from the first membrane 41 are assumed to be dU′ and Ψ′_{U>S>L phase} respectively. The individual assumed data of the amplitude change coefficient and phase information of the electron wave originating from the sample 40 are assumed to be dS′ and phase information Ψ′_{S>L} phase respectively. The individual assumed data of the phase information of the electron wave originating from the second membrane 42 is assumed to be Ψ′_{L phase}. Incidentally, as the initial value of the individual assumed data, it is conceivable to use the amplitude change coefficient (dU+dS) =−logΨ_{obsL amp} and phase information Ψ_{obsL phase} obtained as experimental data, which are backprojected, but others except for the backprojection may be used. Then, the assumed data calculating unit 22 calculates the amplitude change coefficient (dU′+dS′) and phase information Y′_{obsL phase} of the electron wave in the second membrane 42 by superimposing the individual assumed data. That is, regarding the image focused on the second membrane 42, it is possible to obtain assumed data of the amplitude change coefficient (dU′+dS′) and phase information Ψ′_{obsL phase} for each incident angle.

Further, the assumed data calculating unit 22 corrects the individual assumed data by comparing the assumed data with the experimental data. More specifically, the assumed data calculating unit 22 calculates the difference (error) between (dU+dS) and (dU′+dS′) for the amplitude change coefficient for each incident angle, and calculates the difference (error) between Ψ_{obsL phase} and Ψ′_{obsL phase} for the phase information for each incident angle. Thereafter, the assumed data calculating unit 22 determines whether or not the sum of the differences for each incident angle is a predetermined threshold or less. When the sum of the differences exceeds the threshold, the assumed data calculating unit 22 corrects the individual assumed data and then calculates the assumed data again, and determines whether or not the sum of the differences from the experimental data is less than or equal to the predetermined threshold. Subsequently, the same processing is repeated until the total difference becomes less than or equal to the predetermined threshold. Note that instead of the sum of the differences, the average of the differences or the like may be used for the determination.

When it is determined that the sum of the differences is less than or equal to the predetermined threshold, the assumed data calculating unit 22 regards the individual assumed data at that time as the amplitude change coefficient and phase information of the electron wave originating from each layer. Of the information on the electron waves each originating from each layer obtained in this manner, what is particularly needed is the information on the electron wave originating from the sample 40 to be observed. Then, the amplitude information Ψ_{S>L amp} of the electron wave originating from the sample 40 can be calculated based on the amplitude change coefficient ds. However, the amplitude information Ψ_{S>L amp} and phase information Ψ_{S>L phase} calculated at this time are those in a state in which the second membrane 42 is in focus. Therefore, the focal point changing unit 21 of the control device 2 changes the focal position from the second membrane 42 to the sample 40 for the amplitude information Ψ_{S>L amp} and phase information Ψ_{S>L phase} of the electron beam originating from the sample 40. This makes it possible to separate and remove the electron beams originating from the first membrane 41 and the second membrane 42, and obtain the original amplitude information Ψ_{S amp} and phase information Ψ_{S phase} of the sample 40 with high accuracy, thereby improving the image quality of the sample 40.

### Second Embodiment

The second embodiment is an example in which the amplitude and phase of electron wave information originating from each layer are separated by machine learning from electron wave information in a state in which the third layer (second membrane 42) is in focus. In the present embodiment, the amplitude and phase of the electron waves originating from the three layers for the hologram image for each incident angle are learned in advance and generated as a learning model. Then, when an actual hologram image is acquired from the transmission type electron microscope 1, the control device 2 outputs the amplitude and phase of the electron waves originating from the three layers, based on the learning model. Note that unsupervised learning may be used for machine learning.

### Third Embodiment

The above-described first and second embodiments are configured to calculate the amplitude and phase of the electron wave originating from each layer when the electron beam 3 is made incident on the three layers comprised of the first membrane 41, the sample 40, and the second membrane 42, whereas the third embodiment is configured to calculate the amplitude and phase of the electron wave originating from each layer when the electron beam 3 is made incident on two layers. Here, the first layer is described as the sample 40, and the second layer on the downstream side (lower side) of the first layer is described as a membrane, but the first layer may be a membrane, and the second layer downstream (below) of the first layer may be the sample 40.

When the control device 2 acquires hologram images for each angle of incidence from the transmission type electron microscope 1 and reproduces the amplitude information Ψ_{obs amp} and phase information Ψ_{obs phase}, the focal position changing unit changes the focal position to the membrane, and obtains amplitude information Ψ_{obsL amp} (amplitude change coefficient dS) and phase information Ψ_{obsL phase} as experimental data. Further, the assumed data calculating unit 22 of the control device 2 individually assumes the amplitude (amplitude change coefficient) and phase of the electron wave originating from each layer, based on the amplitude information Ψ_{obsL amp} (amplitude change coefficient dS) and the phase information Ψ_{obsL phase}, and superimposes these to thereby obtain amplitude information Ψ′_{obsL amp} (amplitude change coefficient dS′) and phase information Ψ′_{obsL phase} as assumed data. Further, the assumed data calculating unit 22 corrects the individual assumed data by comparing the assumed data with the experimental data and thereby obtains amplitude information Ψ_{S>L amp} and phase information Ψ_{S>L phase} of the electron wave originating from the sample 40. Thereafter, the focal position changing unit changes the focal position from the membrane to the sample 40 for the amplitude information Ψ_{S>L amp} and phase information Ψ_{S>L phase}. This makes it possible to separate and remove each electron wave originating from the membrane, and obtain the original amplitude information Ψ_{S amp} and phase information Ψ_{S phase} of the sample 40 with high accuracy, thereby improving the image quality of the sample 40.

The present invention is not limited to the embodiments described above, and can be modified in various ways. For example, in each of the above-described embodiments, the control device 2 that is the analysis PC is configured to be provided separately from the control PC 15 of the transmission type electron microscope 1, but the analysis PC and the control PC 15 may be configured to be provided as an integrated unit in the transmission type electron microscope 1. Further, in each of the above-described embodiments, the correction of the individual assumed data is terminated when the sum of the differences between the experimental data and the assumed data becomes a predetermined threshold or less, but it may be adapted to perform corrections a predetermined number of times or more and adopt the individual assumed data that results in the smallest difference out of those.

Further, the embodiments described above have been described in detail to simply describe the present invention, and are not necessarily required to include all the described configurations. In addition, part of the configuration of one embodiment can be replaced with the configurations of other embodiments, and in addition, the configuration of the one embodiment can also be added with the configurations of other embodiments. In addition, part of the configuration of each of the embodiments can be subjected to addition, deletion, and replacement with respect to other configurations.

### LIST OF REFERENCE SIGNS

1: transmission type electron microscope
2: control device
3: electron beam
4: electron source
5: converging lens
6: deflector
7: objective lens
8: electron beam biprism
9: imaging lens system
10: fluorescent plate
11: camera
12: goniometer
13: sample holder
14: membrane type holder
15: control PC
16: display device
17: electron beam tilt angle setting unit
18: electron beam tilt direction setting unit
19: start button
21: focal point changing unit
22: assumed data calculating unit
31: inclined electron beam
40: sample
41: first membrane
42: second membrane
43: focal position

1. A microscope system comprising:
a microscope which deflects an electron beam incident on a first layer, a second layer, and a third layer to acquire multiple pieces of electron wave information; and
a control device which changes a focal position of the multiple pieces of electron wave information acquired by the microscope to the third layer, and calculates the amplitudes and phases of electron waves originating from the first layer, the second layer, and the third layer, respectively based on the amplitudes and phases included in the electron wave information after the focal position is changed.

2. The microscope system according to claim 1, wherein
the microscope includes:
an electron source which emits an electron beam;
a deflector which deflects the electron beam;
a holding unit which holds the first layer, the second layer, and the third layer; and
an imaging unit which acquires a hologram image of the electron beam transmitted through the first layer, the second layer, and the third layer in that order,
the control device includes:
a focal point changing unit which changes a focal position to the third layer with respect to the amplitude and phase corresponding to the hologram image acquired by the imaging unit for each incident angle; and
an assumed data calculating unit which individually assumes the amplitude and phase of the electron wave originating from each layer and superimposes the individual assumed data of amplitude and phase, to calculate assumed data of the amplitude and phase for each incident angle with the focal position as the third layer, and
the assumed data calculating unit corrects the individual assumed data by comparing the assumed data for each incident angle with experimental data acquired by the focal point changing unit for each incident angle.

3. The microscope system according to claim 2, wherein
the first layer is a first membrane, the second layer is a sample, and the third layer is a second membrane, and
the focal point changing unit changes a focal position from the second membrane to the sample with respect to the amplitude and phase of the electron wave originating from the sample among the individual assumed data corrected by the assumed data calculating unit.

4. The microscope system according to claim 1, wherein
the control device separates, by machine learning, the amplitudes and phases of the electron waves originating from the first layer, the second layer, and the third layer from the electron wave information in which the focal position is changed to the third layer.

5. A microscope system comprising:
a microscope which deflects an electron beam incident on a first layer and a second layer to acquire multiple pieces of electron wave information; and
a control device which changes a focal position of the multiple pieces of electron wave information acquired by the microscope to the second layer, and calculates the amplitudes and phases of electron waves originating from the first layer and the second layer, respectively based on the amplitudes and phases included in the electron wave information after the focal position is changed.
